(19) United States
(12) Patent Application Publication
(10) Pub. No.: US 2024/0292587 A1
(43) Pub. Date: Aug. 29, 2024

(54) Improving Processing of a Flexible Circuit Board (CB) Using a Vacuum Plate Adapted to the CB Design

(71) Applicant: Orbotech Ltd., Yavne (IL)

(72) Inventors: Rami KELLER, Tel Aviv (IL); Tal GOICHMAN, Kiryat Ono (IL)

(21) Appl. No.: 18/573,214

(22) PCT Filed: Oct. 12, 2022
(86) PCT No.: PCT/IB2022/059768

§ 371 Date: Dec. 21, 2023

Related U.S. Application Data
(60) Provisional application No. 63/283,218, filed on Nov. 25, 2021.

(51) Int. Cl. H05K 13/00; B25B 11/00

(52) U.S. Cl. CPC H05K 13/0069; B25B 11/005

(57) ABSTRACT

A system includes a plate and a vacuum source. The plate has a first surface and a second surface opposite the first surface, the plate is configured to receive on the first surface a flexible substrate including a first section having a first flexibility and a second section having a second flexibility different from the first flexibility, the plate has through-holes (TH), between the first and second surfaces, with a variable density that varies from a first pattern arranged in a first density opposite the first section to a second pattern arranged in a second density, different from the first density, opposite the second section. The vacuum source is configured to draw a vacuum in the TH between the first and second surfaces for fixing the first section to the first pattern and the second section to the second pattern.

### FIELD OF THE INVENTION

The present invention relates generally to production of electronic devices, and particularly to methods and systems for improving processing of flexible circuit boards.

### BACKGROUND OF THE INVENTION

Flexible circuit boards (CBs) are used in various types of electronic devices and systems. Various techniques for improving the flatness of flexible CBs during production processes have been published.

For example, U.S. Pat. No. 6,966,560 describes a device or chuck for fixing thin and/or flexible substrates allows a uniform and all-over sucking-up of the substrates without any disadvantageous warping or bending. The chuck has notches and holes communicating with a plurality of microgrooves arranged on the bearing surface. If a vacuum device sucks off air through the bores and the notches, a vacuum extends in the microgrooves so that a substrate located on the bearing surface is sucked up.

U.S. Reissued Pat. RE43,736 describes a vacuum hold down table that includes a surface sheet having perforations arranged so as to reduce surface cracking when the surface sheet is subject to forces during use of the table. The perforations may also be arranged so that a greater hold down force is produced in that portion of the table where the workpiece will be located, this may be accompanied by varying the hole diameter and/or hole spacing.

### SUMMARY OF THE INVENTION

An embodiment of the present invention that is described herein provides a system including a plate and a vacuum source. The plate has a first surface and a second surface opposite the first surface, the plate is configured to receive on the first surface a flexible substrate including a first section having a first flexibility and a second section having a second flexibility different from the first flexibility, the plate has through-holes (TH), between the first and second surfaces, with a variable density that varies from a first pattern arranged in a first density opposite the first section to a second pattern arranged in a second density, different from the first density, opposite the second section. The vacuum source is configured to draw a vacuum in the TH between the first and second surfaces for fixing the first section to the first pattern and the second section to the second pattern.

In some embodiments, at least one of the TH has a first cavity extended from the first surface into the plate and having a first shape, and a second cavity that is: (i) extended from the second surface into the plate, (ii) connected to the first cavity and (iii) having a second shape, at least one of the first and second shapes includes a conical shape. In other embodiments, when all the TH have the first cavity, at least twenty percent of the first surface is perforated with the first cavity. In yet other embodiments, at least one of the TH has a diameter, which is measured on the first surface, and is smaller than 1 mm.

In an embodiment, the plate includes stainless steel. In another embodiment, the system includes one or more pillars, which are formed on the second surface between two or more adjacent TH, and are configured to improve a uniformity of the vacuum applied through the plate. In yet another embodiment, at least one of the pillars has a conical shape.

In some embodiments, the flexible substrate has a third section, which is positioned between the first section and the second section and has a third flexibility, which is smaller than the first flexibility and larger than the second flexibility, the plate has a third pattern, which is positioned between the first pattern and the second pattern and is arranged in a third density opposite the third section, and the third density is smaller than the first density and larger than the second density. In other embodiments, the variable density varies gradually from the first density to the second density via the third density. In yet other embodiments, the flexible substrate includes a flexible circuit board, and the vacuum source is configured to draw the vacuum in the TH for performing on the flexible circuit board at least a process selected from a list of processes consisting of: (i) a production process, (ii) a repairing process, and (iii) an inspection process.

There is additionally provided, in accordance with an embodiment of the present invention, a method for producing a plate for fixing thereto a flexible substrate including a first section having a first flexibility and a second section having a second flexibility different from the first flexibility, the method includes, in a plate having a first surface and a second surface opposite the first surface, producing multiple first cavities extended from the first surface into the plate and having a first shape. Multiple second cavities that are extended from the second surface into the plate and having a second shape, are produced, a plurality of the second cavities is connected to a plurality of the first cavities, respectively, and break through the plate for producing multiple through-holes (TH) between the first and second surfaces.

In some embodiments, the TH are arranged in a variable density that varies from a first pattern arranged in a first density opposite the first section, to a second pattern arranged in a second density, different from the first density, opposite the second section. In other embodiments, producing the multiple first cavities including applying a first lithography process for defining on the first surface the first and second patterns of the TH. In yet other embodiments, producing the multiple first cavities including applying a first etching process for transferring, into the plate, the first and second patterns defined in the first lithography process.

In an embodiment, producing the multiple second cavities including applying a second lithography process for defining on the second surface the first and second patterns of the TH, in the second lithography process: (i) the first pattern of the second lithography process is aligned with the first pattern of the first lithography process, and (ii) the second pattern of the second lithography process is aligned with the second pattern of the first lithography process. In another embodiment, producing the multiple second cavities includes applying a second etching process for transferring, into the plate, the first and second patterns defined in the second lithography process, and applying the second etching process includes breaking through the plate for connecting between the second cavity and the first cavity. In yet another embodiment, at least one of the first and second etching process includes a wet etching process.

In some embodiments, the method includes producing on the second surface one or more pillars positioned between the second cavities. In other embodiments, producing at least one of the pillars by applying to the plate a lithography process and an etching process.

The present invention will be more fully understood from the following detailed description of the embodiments thereof, taken together with the drawings in which:

### BRIEF DESCRIPTION OF THE DRAWINGS

FIG. 1 is a schematic, pictorial illustration of a system for processing a flexible circuit board (CB), in accordance with an embodiment of the present invention;

FIG. 2 is a schematic pictorial illustration of the flexible CB and a sectional view of a vacuum plate of the system of FIG. 1, in accordance with an embodiment of the present invention; and

FIG. 3 is a flow chart that schematically illustrates a method for producing the vacuum plate of FIG. 2, in accordance with an embodiment of the present invention.

### DETAILED DESCRIPTION OF EMBODIMENTS

### Overview

Some electronic devices and/or systems comprise one or more flexible devices, such as flexible circuit boards (CBs) that have circuits printed therein and are configured to connect between components mounted thereon. Such flexible CBs are produced using various types of processes, such as lamination of flexible substrates and layers, metal coating and patterning, as well as inspection and repairing processes.

In some cases, flexible CBs and other sorts of thin devices may warp or bend during the process, which may result in distortions in the printed circuits and/or inability to perform inspection and repairing processes in the printed circuits. Typically, edge sections of flexible CBs tend to bend, but other sections of the CB may also warp due to the design of the product printed on the CB that may affect the flexibility level of different sections of the CB, as will be described herein. Therefore, during the production process, it is important to fixate all the sections of the flexible CB to a chuck or a mount (e.g., a stage) of the processing and/or inspection and/or repairing system(s). In the context of the present disclosure and in the claims, the term “flexibility” of the CB or grammatical variation thereof refers to “warpability” of the CB. In other words, the extent to which the CB is prone to be distorted or warped in response to conditions and/or forces applied thereto.

Embodiments of the present invention that are described hereinbelow provide improved techniques for fixating a flexible circuit board (and other sorts of flexible substrates) to a vacuum plate for performing various types of process steps on the flexible circuit board. Moreover, embodiments of the present invention provide improved design and production techniques of the vacuum plate.

In some embodiments, a system for processing a flexible CB comprises a vacuum plate, also referred to herein as a plate, and a vacuum source, such as a vacuum pump.

In some embodiments, the plate has a first surface and a second surface opposite the first surface. The plate is configured to receive on the first surface a flexible substrate of the CB that comprises a first section having a first flexibility and a second section having a second flexibility different from the first flexibility.

In some embodiments, the plate has through-holes (TH), formed through the plate between the first and second surfaces. The TH are arranged along and across the plate in a variable density that varies from a first pattern arranged in a first density opposite the first section of the CB, to a second pattern arranged in a second density, different from the first density, which is opposite the second section of the CB.

In some embodiments, the vacuum source is configured to draw vacuum in the TH between the first and second surfaces for fixing the first section of the CB to the first pattern of the plate, and the second section of the CB to the second pattern of the plate. In other words, the density of the TH in the plate is adapted to the design of the product printed in the CB. For example, in a pattern of the plate that is intended to be opposite a section of the CB that is prone to bend or warp (e.g., an edge section or a very thin or flexible section of the CB), the density of TH in the plate is high, e.g., between about 20% and 40% of the total area of the plate. In other words, at least 20% of the plate is perforated with the TH. The high density of TH enables application of a stronger vacuum force between the plate and the CB, so as to improve the coupling therebetween. Note that improved coupling between the plate and the CB results in a better fixation and flattening of the CB, and therefore, to improved quality of the production process performed on the CB while being fixed to the vacuum plate. Similarly, the density of TH may be lower (e.g., lower than about 20% or 10%) in a pattern of the plate intended to be opposite a section that is positioned at the center of the CB and has a relatively low flexibility (e.g., lower than that of the aforementioned edge section).

In some embodiments, a typical warpage level of the CB is between about 0.1 mm and 5 mm. The effect of the force applied for straightening (e.g., flattening) the warped CB is obtained by increasing the flow rate (i.e., suction) of the air into the vacuum source due to increased density of the through holes. In other words, each TH that has a given diameter produces a suction flow corresponding to its area out of the total area of the through holes. In the present example, the vacuum source is configured to produce the vacuum by applying to the vacuum plate an absolute pressure between about 0.25 Bar and 0.5 Bar. Note that the term straightening refers to applying the planarity of the vacuum plate to the CB.

In some embodiments, the design of each vacuum plate is adapted to the design of the product intended to be produced in the circuit board. For example, some CBs have via-holes that are produced through the entire thickness of the CB. Such via-holes may allow ventilation that may reduce the vacuum applied between the plate and the CB.

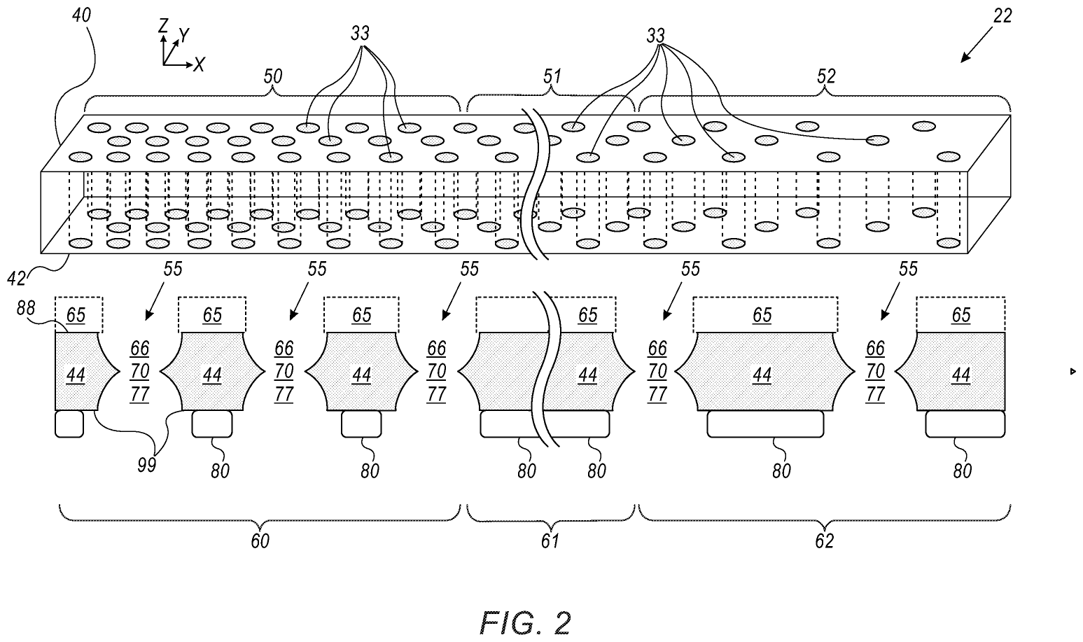

In some cases, a given product may have a large number of via holes in a first section of the CB and a smaller or no via-holes in a second section of the CB. Thus, applying the same vacuum to the first and second sections may result in insufficient local vacuum force and bending of the first section. In some embodiments, a given vacuum plate is adapted to the given product by having a higher density of TH opposite the first section and a lower density of TH opposite the second section. In such embodiments, the higher density of TH enables application of higher vacuum force between the plate and the first section of the CB, so as to maintain a suitable vacuum level along the interface between the vacuum plate and the CB. These embodiments are depicted in detail in FIG. 2 below.

In principle it is possible to apply vacuum for fixing a (flexible) substrate to a vacuum table. Such tables may have drills or bores formed through the table for applying the vacuum. It is possible to produce such bores using laser drilling or mechanical drilling techniques, however, such techniques typically limit the minimal size and/or the maximal density of the bores. For example, when using a drilling technique, the maximal density of bores may assume about 7% or 10% of the total size of the table. Moreover, drilling one bore at a time may consume time and may increase the cost of such vacuum tables.

In some embodiments, the disclosed vacuum plate is produced using Very large-scale integration (VLSI) processes. Specifically, a lithography process is configured to define the pattern of the TH by patterning a photoresist layer on the surface of the plate. Subsequently, an etching process is configured to transfer the defined pattern into the plate. Such VLSI processes improve the control of the size, density and lateral distribution of the TH. Moreover, all the TH are defined using one set of lithography mask(s), and therefore, are produced at the same time. Thus, VLSI processes substantially reduce the processing time of forming the TH, and therefore, the cost associated with the producing the vacuum plate.

In principle, it is possible to apply any suitable processing techniques for producing the pattern of the TH in the plate. For example, computer numerical control (CNC) machining, or punching, or laser-based machining, or electrical discharge machining (EDM) can be used for producing the TH. Such processes, however, may (i) increase the cost of producing the TH (e.g., CNC, laser machining and EDM), (ii) introduce thermal stress that may cause distortion in the plate (e.g., CNC, punching, and laser machining), (iii) cannot produce the required profile of the three-dimensional (3D) shape of the TH (e.g., punching and laser machining), and (iv) leave residues, such as burrs, on the vacuum plate (e.g., laser machining). Another option is to apply to the plate a wet etching process, which is configured to form a cavity that extends from the surface of the plate into the bulk of the plate. Wet etching processes typically use a liquid substance having one or more etching agents that are configured to produce a conical profile of the TH. Alternatively, the wet etching process is configured to etch the plate isotropically. In the context of the present disclosure, the term “isotropic” refers to a uniform etching rate (of the etching liquid placed in contact with the plate) in all directions. Thus, wet etching typically results in forming a cavity having a conical shape or a hemisphere shape.

In some embodiments, the TH are produced by applying first and second patterning processes to the first and second surfaces of the plate, respectively. In such embodiments, the first patterning process comprises, (i) a first lithography process applied to the first surface of the plate for defining, in a first photoresist layer, the first and second patterns on the first surface, and subsequently (ii) a first wet etching process is applied to the first surface of the plate for transferring the first and second patterns of the first photoresist layer, into the plate. After the first patterning process, a set of first cavities are produced in accordance with the first and second patterns, note that the first cavities extend from the first surface into the bulk of the plate, e.g., the depth of the first cavities is about 50% of the thickness of the plate. Note that after the first wet etching process, the first photoresist layer is removed from the first surface using any suitable resist removal process.

In other embodiments, the depth of the first cavities is substantially smaller than about 50% of the thickness of the plate, and a second cavity whose process flow is described herein, has a depth larger than about 50% of the plate thickness, so as to produce the TH.

In some embodiments, the second patterning process is applied to the second surface of the plate (e.g., after concluding the first patterning process). The second patterning process comprises (i) applying a second lithography process using the same techniques of the first lithography process that are described above. Note that in the second lithograph process, the first and second patterns of the TH that are defined on the second surface are aligned, respectively, with the first and second patterns of the TH that are defined on the first surface, and subsequently (ii) a second wet etching process is applied to the second surface for producing a second cavity that extends from the second surface into the plate using the techniques described in the first wet etching process above. Note that the second wet etching process is configured to etch the plate so that the at least one of and typically each pair of the first and second cavities are connected for producing the through-holes (TH) in the plate.

In other words, the second wet etching process is configured to break through the plate into the first cavities, so that the pairs of first and second cavities constitute together the respective TH. Note that the alignment of the second lithography process is important for having each pair of the first and second cavities aligned, so as to produce the respective TH in accordance with the first and second patterns.

The inventors found that applying wet etching processes to both first and second surfaces of the plate are configured to increase the density of the TH, and therefore, the vacuum applied between the plate and the CB.

The disclosed techniques improve the quality of producing flexible printed circuit boards and other thin and/or flexible devices. Moreover, the disclosed techniques improve the quality of vacuum plates and reduce the cost associated with producing such vacuum plates.

### System Description

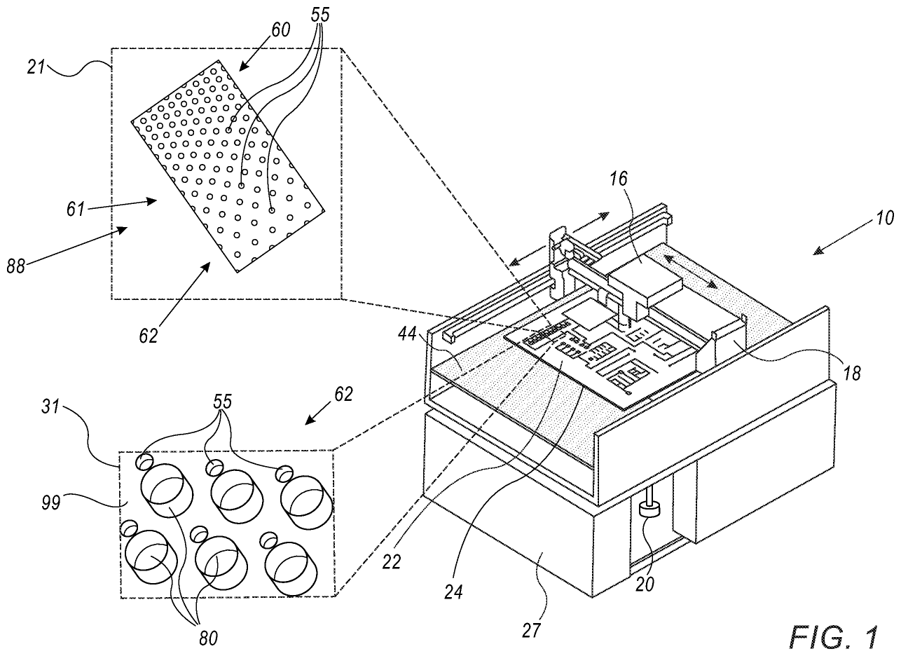

FIG. 1 is a schematic, pictorial illustration of a system 10 for processing a flexible circuit board (CB) 22, in accordance with an embodiment of the present invention.

In some embodiments, system 10 is configured to print various materials on a flexible substrate 24 of an electronic circuit, referred to herein as flexible CB 22. In the present example, CB 22 is printed on flexible substrate 24, but in other embodiments, system 10 is configured to produce, repair or inspect any other suitable type of device or product, such as but not limited to a flexible or rigid flat panel display (FPD), a rigid printed circuit board (PCB) or a flexible or rigid integrated circuit (IC) substrate, which is held on a vacuum plate 44 described in detail below.

In the context of the present disclosure, the term “produce” is referred to any suitable production process step(s) carried out in system 10. For example, deposition of one or more substances and/or alloys, a laser-induced forward transfer (LIFT) process, a direct writing process, and a suitable etching and/or lithography process. The term “repair” or “repairing” refers to removal of excess pattern or defect, and/or production of a missing pattern. The term “inspect” refers to any suitable type of defect inspection or size measurement of any selected pattern produced on substrate 24. The terms “Flat panel Display,” “FPD,” “printed circuit board,” “PCB,” “integrated circuit substrate,” and “IC substrate” are used herein to refer generally to any suitable substrate on which the aforementioned materials and/or alloys are deposited or inspected.

In an embodiment, system 10 comprises a positioning assembly 18, which is configured to position an optical assembly 16 over desired sites of substrate 24, by moving optical assembly 16 linearly along selected axes of system 10. In some embodiments, positioning assembly 18 may comprise a moving bridge configured to move along one or more axes, e.g., horizontal axes X, Y, and a vertical axis Z. In other embodiments, positioning assembly 18 may comprise a moving stage. Alternatively, other suitable techniques can be used to move positioning assembly 18 and CB 22 relative to one another. A control unit 27 controls several functionalities of system 10, such as the operation of optical assembly 16 and positioning assembly 18.

Control unit 27 typically comprises a general-purpose computer, which is programmed in software to carry out the functions described herein. The general-purpose computer can include any suitable processor known in the art. The software may be downloaded to the computer in electronic form, over a network, for example, or it may, alternatively or additionally, be provided and/or stored on non-transitory tangible media, such as magnetic, optical, or electronic memory.

In some embodiments, flexible CB 22 is positioned on vacuum plate 44, which is configured to flatten CB 22 using a vacuum-based force. Note that the flexibility of CB 22 may result in one or more sections of CB 22 that may not be fully attached or coupled to the surface of vacuum plate 44, so that the vacuum applied between CB 22 and vacuum plate 44 couples therebetween and flattens all the sections of CB 22 on the surface of vacuum plate 44.

Reference is now made to insets 21 and 31 showing, respectively, (i) a top view of an upper surface 88, also referred to herein a first surface, of a section of vacuum plate 44, and (ii) a bottom view of a lower surface 99, also referred to herein a second surface, of a section of vacuum plate 44. Note that after vacuum is applied upper surface 88 has a planarity between about 50 μm and 200 μm, measured over the entire area of CB 22, so as to retain CB 22 flat for performing the production and/or repairing and/or inspection processes described above. In some embodiments, vacuum plate 44 has holes, also referred to herein as through-holes (TH) 55, formed through plate 44 between surfaces 88 and 99.

In some embodiments, CB 22 has multiple sections (shown in detail in FIG. 2 below), at least three of the sections have three different patterns, respectively. In some cases, the pattern difference may result in a different flexibility of CB 22 and/or in a different density of via-holes (shown in FIG. 2 below) formed through CB 22. Note that such via-holes may affect the vacuum level applied between CB 22 and vacuum plate 44 because the via-holes may allow ventilation that may reduce the vacuum applied between vacuum plate 44 and CB 22.

In the example shown in inset 21, TH 55 are arranged in three section 60, 61 and 62, each of which has a different density of TH 55. In some embodiments, the cumulative area of TH 55 is between about 5% and 45% of the total area of surface 88. In the example of section 60, the cumulative area of TH 55 accounts for about 40% of the total area of surface 88, whereas in the example of section 62, the cumulative area of TH 55 accounts for about 10% of the total area of surface 88. Note that the density of TH 55 is formed in accordance with the flexibility level and/or the number of via-holes formed through CB 22, as will be shown, and described in detail in FIG. 2 below.

In the context of the present disclosure and in the claims, the terms “about” or “approximately” for any numerical values or ranges indicate a suitable dimensional tolerance that allows the part or collection of components to function for its intended purpose as described herein.

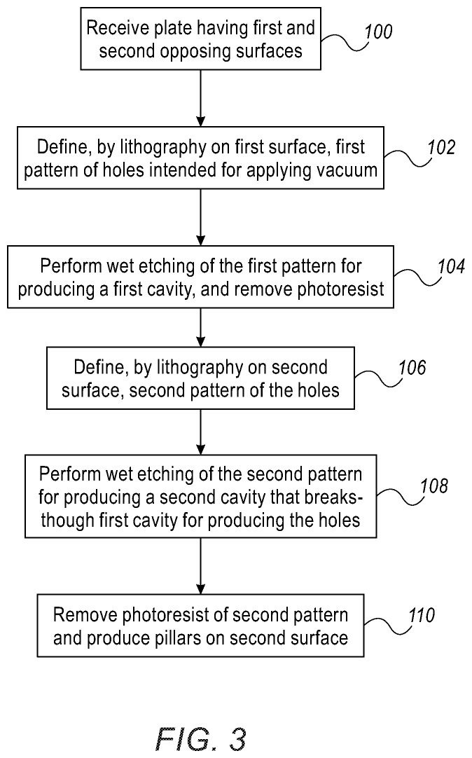

Reference is now made to inset 31 showing the bottom view of section 62 of surface 99, having TH 55 formed therethrough and pillars 80 formed thereon. In accordance with the description of inset 21 above, the cumulative area of TH 55 accounts for about 10% of the total area of surface 99, and pillars 80 are formed between TH 55 using suitable production processes described in FIGS. 2 and 3 below.

In some embodiments, the perforated plate (e.g., vacuum plate 44) is supported in multiple points to prevent formation of a sag due to the force applied by the weight and vacuum. The density of support points determines the size of the plate sag (typically smaller than about one micrometer). Increased density of the support grid reduces the sag but also reduces the distribution of the applied vacuum.

In some embodiments, pillars 80 are formed on surface 99 and are configured for producing an air gap between the supporting points and the TH, so that the airflow that produces the vacuum can be distributed evenly between the through holes. In an embodiment, pillars 80 may have any suitable shape, such as the pillar shape shown in inset 31, or a cone shape or any other suitable shape.

Reference is now made back to the general view of FIG. 1. In some embodiments, system 10 comprises a vacuum source 20, in the present example a vacuum pump, which is configured to draw vacuum in TH 55 between surfaces 88 and 99 for fixing the corresponding sections of CB 22 (shown in FIG. 2 below) to sections 60, 61 and 62 of vacuum plate 44. In an embodiment, vacuum source 20 is configured to produce the vacuum by applying to vacuum plate 44 an absolute pressure between about 0.25 Bar and 0.5 Bar or any other suitable pressure. In the example of FIG. 1, vacuum source 20 is positioned below surface 99 of vacuum plate 44, and is configured to apply the vacuum though TH 55 for fixing CB 22 to surface 88 of vacuum plate 44.

In some embodiments, system 10 may have a different vacuum plate 44 for each product of CB 22, so as to optimize the flattening and fixing of each CB 22 to the corresponding vacuum plate 44. Moreover, the density and distribution of TH 55 within each vacuum plate 44 are designed to apply a larger draw force (by the vacuum) at the edge of CB 22 and a smaller draw force at the center of CB 22. This design is applied because flexible CBs, such as CB 22 typically tend to warp or bend at the edges more than at the center.

Reference is now made back to inset 21. In some embodiments, TH 55 of section 60 are arranged in a first gradual density and TH 55 of section 62 are arranged in a second gradual density, which is different from the first gradual density. In the context of the present invention and in the claims, the term “gradual density” refers to a variable density of TH 55 that varies be degrees along the respective section, similar to a grey-level of a black and white color scale.

In some embodiments, TH 55 may be arranged using a variable density that varies from a first density opposite a first section of CB 22 (having a first flexibility) to a second density, different from the first density, opposite a second section of CB 22 (having a second density different from the first flexibility).

In other embodiments, TH 55 may be arranged along and/or across sections 60-62 of vacuum plate 44 using any suitable distribution and density. For example, in case a given section at the center of CB 22 has no via-holes, or a very small amount of via-holes, the corresponding section of vacuum plate 44, which is intended to be positioned opposite the given section of CB 22, may not have any TH 55, or a very small density of TH. Similarly, an edge section of CB 22 typically tends to detach from vacuum plate 44 and to warp or bend upwards, e.g., toward optical assembly 16. Thus, the corresponding edge section of vacuum plate 44, which is intended to be positioned opposite the edge section of CB 22, typically has a high density of TH 55 for improving the vacuum-induced coupling (i.e., fixing) between the corresponding edge sections of CB 22 and vacuum plate 44.

### Vacuum Plate Having Through-Holes Arranged in a Variable Density

FIG. 2 is a schematic pictorial illustration of CB 22 and a sectional view of vacuum plate 44, in accordance with an embodiment of the present invention.

In some embodiments, CB 22 has surfaces 40 and 42, and via-holes 33 that pass-through CB 22, between surfaces 40 and 42. Note that typically CB 22 has additional components that are not shown for the sake of conceptual clarity. For example, CB 22 typically comprises multiple stacked flexible layers. At least one layer, and typically all layers, comprising electrically conducting traces formed within the layer or on an outer surface of the layer. CB 22 typically comprises electrically conducting contact holes or vias for connecting between the traces of each layer.

In some embodiments, CB 22 has sections 50, 51 and 52, wherein from among sections 50-52, (i) section 50 has the highest density of via-holes 33, also referred to herein as a first density, (ii) section 52 has the lowest density of via-holes 33, also referred to herein as a second density, and (iii) section 51 has via-holes 33 arranged in a third density, smaller than the first density and larger than the second density. Note that CB 22 is presented in an isometric view in order to show the altering or varying (e.g., gradually changing) density of via-holes 33 in the different sections of CB 22.

In some embodiments, vacuum plate 44 has upper surface 88, lower surface 99 and TH 55 formed through vacuum plate 44, between surfaces 88 and 99. Moreover, vacuum plate 44 has a section 60, which is opposite section 50 and is intended to be placed in contact with section 50 of CB 22, similarly, a section 62 of vacuum plate 44 is intended to be placed in contact with section 52 of CB 22, and a section 61 of vacuum plate 44 is intended to be placed in contact with section 51 of CB 22. Note that sections 51 and 61 have a drawing indicative of discontinuity for showing that the actual size of these sections and of CB 22 and vacuum plate 44 can be larger than that shown in FIG. 2. In some embodiments, the density of TH 55 in each section of vacuum plate 44 corresponds to the density of via-holes 33 in the respective section of CB 22 intended to be placed in contact therewith. For example, section 50 of CB 22 has the highest density of via-holes 33, and section 60 of vacuum plate 44 has the highest density of TH 55. Similarly, section 52 of CB 22 has the lowest density of via-holes 33, and section 62 of vacuum plate 44 has the lowest density of TH 55. Note that the gradual change in the density of TH 55 of vacuum plate 44 corresponds to the gradual change in the density of via-holes 33 of CB 22. Note that a larger density of TH 55 increases the vacuum that draws CB 22 to surface 88 of vacuum plate 44.

In other embodiments, the number of via-holes 33 in CB 22 may be substantially smaller than the amount shown in FIG. 2, and the edge sections of CB 22 typically tend to detach from surface 88 of vacuum plate 44. In such embodiments, the density of TH 55 at the edge sections of vacuum plate 44 is higher compared to that at the center of vacuum plate 44, so as to improve the coupling between vacuum plate 44 and CB 22, and to obtain contact between surfaces 42 and 88 across the entire area of vacuum plate 44 and CB 22.

In some embodiments, TH 55 are formed using a lithography process for pattern definition, and subsequently a wet etching process for producing TH 55. In the present example, the pattern of TH 55 is defined using a photoresist layer 65, which is formed on surface 88 and is patterned using any suitable lithography process. The pattern formation may be carried out using: (i) a mask-based photolithography, or (ii) a direct imaging process.

In the mask-based process, a photoresist layer is applied to the surface of the layer intended to be patterned, subsequently a mask is used for defining the pattern, e.g., by covering the pattern leaving areas out of the pattern exposed. Subsequently, applying suitable light to the exposed area of the photoresist followed by developing the exposed area, so as to complete the pattern definition in photoresist layer 65.

In the direct imaging process, after applying the photoresist layer to the surface of the layer intended to be patterned, the pattern is produced in the photoresist by applying the light, which is shaped for producing the pattern directly to the photoresist layer, without using a mask.

In some embodiments, the lithography process is carried out using a Photoetching system model ALDS-Power4 produced by Adix SA, (Parc d'Affaires des Portes Voie de l'Orée 27100, Val De Reuil, France). Note that the term “photoetching system” refers to a system configured to carry out both lithography and wet etching of TH. The term photoetching is also known as photo chemical machining (PCM) in processes related to patterning of metal sheets or sheets made from other materials that have a thickness (in Z-axis of FIG. 2) smaller than about 3 mm.

In some embodiments, after concluding the lithography process, a wet etching process is used for producing a cavity 66, followed by removal of photoresist layer 65. Note that (i) the pattern defined using the photoresist has sufficient width in at least one of X-axis and Y-axis, so as to compensate for undercutting of plate 44 (shown in FIG. 2 as a notch below photoresist layer 65) during the wet etching, and (ii) photoresist layer 65 does not remain on surface 88 after concluding the formation of cavity 66, and is therefore presented in dashed lines. Moreover, typically cavity 66 has a shape of a conus or a hemisphere produced (shown in XZ plane of FIG. 2) by the wet etching of vacuum plate 44 using a suitable etching agent.

In some embodiments, vacuum plate 44 is made from a suitable type of stainless steel (e.g., SS 304, SS 316) having a thickness of about 1-2 mm or any other suitable thickness between about 0.05 mm and 5 mm. In such embodiments, cavity 66 has a depth larger than about 0.1 mm. In an embodiment, the etching agent comprises a Ferric Chloride Solution or any other suitable type of a wet etching agent.

In some embodiments, a cavity 77 is formed by flipping vacuum plate 44 and using the same lithography and wet etching processes described above. Note that cavity 77 breaks-though vacuum plate 44, e.g., at an interface 70, into cavity 66 for producing TH 55. In other words, after forming cavity 66, the formation of cavity 77 comprises breaking through the material of vacuum plate 44 so as to completely open TH 55.

In some embodiments, cavity 77 may be formed using a multiple (e.g., double or a triple) etching or photoetching process, so as to open interface 70. For example, in case the thickness of plate 44 in Z-axis is about 1.5 mm, cavity 66 may have a depth of about 0.1 mm and cavity 77 may have a depth of about 1.4 mm, so as to fully open TH 55.

In some embodiments, the effective cross section of TH 55 is increased when using wet etching processes, compared to that when using other processing techniques. For example, when using another technique, such as EDM, CNC or laser machining, the walls of TH 55 are approximately orthogonal to surfaces 88 and 99, and have a width (in X axis) of interface 70. The wet etching processes increase the cross-section size of TH 55, and therefore, improve the vacuum level that can be obtained compared to a TH 55 that would have been formed using processes other than wet etching. In other words, the wet etching processes increase the percentage of the area covered by TH 55 relative to the total area of vacuum plate 44.

In some embodiments, pillars 80 may initially be part of the stainless-steel sheet of vacuum plate 44, and may be etched from vacuum plate 44 using a suitable lithography process. In the present example, pillars 80 may have a round or rectangular cross section in an XY plane of an XYZ coordinate system, and may have any suitable thickness in Z axis. In such embodiments, pillars 80 may have the same width in X and Y axes of photoresist layer 65 and may be produced together with cavity 77 using the same lithography process and a different (or a similar) etching process. In other embodiments, a separate set of lithography and etching process may be used for producing pillars 80 and cavity 77.

In other embodiments, pillars 80 may be formed on surface 99 using any suitable technique and may have any suitable shape and size. For example, a round shape in XY plane having a diameter between about 0.1 mm and 2 mm and a thickness between about 0.1 mm and 5 mm in Z axis.

Additional embodiments related to the production process of vacuum plate 44 are described in FIG. 3 below.

Note that each vacuum plate 44 is formed for producing a different product of CB 22, so that after concluding the formation of vacuum plate 44, a user of system 10 selects a suitable vacuum plate 44 for producing a corresponding product of CB 22. During the producing and inspection thereof, CB 22 is placed on vacuum plate 44, such that surface 42 of CB 22 is placed in contact with surface 88 of vacuum plate 44. In the present example, surface 42 of CB 22 is coupled to surface 88 of vacuum plate 44 using the vacuum applied by vacuum source 20, through TH 55, as described in FIG. 1 above. Note that flatness of CB 22 is obtained by maintaining the contact between surfaces 42 and 88. In some cases, one or more sections of CB 22 may detach from surface 88 of vacuum plate 44. The detachment may occur at the edge sections of CB 22, or due to a different flexibility between different sections of CB 22, or at one or more section(s) having a higher density of via-holes 33 that reduce the vacuum force applied between CB 22 and vacuum plate 44.

In some embodiments, TH 55 are arranged using a variable density that varies from section 60, which is opposite section 50 of CB 22, and having a first density to section 62, which is opposite section 62, and having a second density, different from the first density. In other words, a first pattern of TH 55 of section 60, which is intended to be placed in contact with section 50 of CB 22 is arranged in a first density of TH 55, and a second pattern of TH 55, which is intended to be placed in contact with section 52 of CB 22, is arranged in section 62 in a second density of TH 55, different from (e.g., smaller than) the first density of section 60. Moreover, in order to obtain a gradual density of TH 55, e.g., along X axis of vacuum plate 44, the pattern density of TH 55 in section 61 is larger than the pattern density in section 62 and smaller than the pattern density in section 60.

In other embodiments, the density of TH 55 may vary gradually within the same section. In other words, a first pattern of TH 55 of section 60, which is intended to be placed in contact with section 50 of CB 22 is arranged in a first gradual density of TH 55, and a second pattern of TH 55, which is intended to be placed in contact with section 52 of CB 22, is arranged in section 62 in a second gradual density of TH 55, which is different from the first gradual density of section 60.

Additionally, or alternatively, the size of TH 55 may alter gradually or not within the same section of vacuum plate 44, or may be similar within the same section and alter (gradually or not gradually) between different sections of vacuum plate 44. For example, TH 55 of section 60 may have a diameter (e.g. on surface 88) of about 1 mm, TH 55 of section 62 may have a diameter (e.g. on surface 88) of about 0.15 mm, and TH 55 of section 61 may have a diameter (e.g. on surface 88) of about 0.5 mm. Note that in principle it is possible to produce TH 55 as bores or drills using laser drilling or any other suitable drilling technique, however, using Very large-scale integration (VLSI) processes improves the control of the size, the density and the lateral distribution of TH 55, and also reduces the time associated with drilling each TH 55 bore using a laser or a mechanical drilling system. In other words, using VLSI processes reduce the time and cost associated with the production of vacuum plate 44.

In other embodiments, the diameter of TH 55 may alter gradually within the same section. For example, in case section 60 is an edge section of vacuum plate 44, TH 55 at a first side of section 60 (which is closer to the edge of vacuum plate 44) may have the same density but a different diameter compared to TH 55 at a second side of section 60 (which is closer to the center of vacuum plate 44).

In alternative embodiments, the density of TH 55 may alter gradually within the same section. For example, in case section 60 is an edge section of vacuum plate 44, TH 55 at a first side of section 60 (which is closer to the edge of vacuum plate 44) may be arranged in a different (e.g., larger) density of compared to TH 55 arranged in a second side of section 60 (which is closer to the center of vacuum plate 44).

This particular configuration of vacuum plate 44 is shown by way of example, in order to illustrate certain problems that are addressed by embodiments of the present invention and to demonstrate the application of these embodiments in enhancing the performance of a system for producing electronic circuits in a flexible substrate. Embodiments of the present invention, however, are by no means limited to this specific sort of example vacuum plate, and the principles described herein may similarly be applied to other sorts of apparatus for attaching a flexible substrate to a chuck or a stage using vacuum or any other suitable technique.

### Producing a Vacuum Plate

FIG. 3 is a flow chart that schematically illustrates a method for producing vacuum plate 44, in accordance with an embodiment of the present invention.

The method begins at a plate receiving step 100, with receiving vacuum plate having opposing surfaces 88 and 99, as described in detail in FIGS. 1 and 2 above. At a first cavity definition step 102, a lithography process (also referred to herein as a first lithography process) is used for patterning photoresist layer 65 on surface 88 so as to define cavity 66, as described in detail in FIG. 2 above. After step 102, some areas of surface 88 (e.g., the area intended to be cavity 66) that are intended to be etched, are exposed and the other areas of surface 88 remain coated with photoresist layer 65. At a first cavity etching step 104, wet etching (also referred to herein as a first wet etching process) is applied to the exposed areas of surface 88 as defined in step 102 above, so as to form cavity 66, as shown and described in detail in FIG. 2 above. Note that after performing the first wet etching, photoresist layer 65 is removed for concluding step 104, as described in FIG. 2 above.

At a second cavity definition step 106, vacuum plate 44 is flipped and a lithography process (also referred to herein as a second lithography process) is used to pattern photoresist layer 65 on surface 99 for defining cavity 77, as described in detail in FIG. 2 above. After step 106, some areas of surface 99 (e.g., areas intended to be cavity 77) that are intended to be etched, are exposed and the other areas of surface 99 remain coated with photoresist layer 65. At a second cavity etching step 108, a wet etching process (also referred to herein as a second wet etching process) is applied to the exposed areas of surface 99 for producing cavity 77, as described in detail in in FIG. 2 above.

At a pillar production step 110 that concludes the method, pillars 80 are produced on surface 99. In some embodiments, pillars 80 may be produced by depositing a layer on surface 99, and patterning the layer for producing pillars 80. In other embodiments, pillars 80 are part of vacuum plate 44 and are patterned in vacuum plate 44 using a suitable lithography and etching process. In alternative embodiments, pillars 80 are part of vacuum plate 44 and are patterned in vacuum plate 44 using the same lithography and etching process used for patterning cavity 77.

In yet other embodiments, after performing the wet etching of step 108, photoresist layer 65 is removed for concluding step 108 and before moving to step 110.

The method and process flow of FIG. 3 is simplified for the sake of conceptual clarity and several process steps, such as but not limited to, surface preparation and cleaning, are omitted intentionally.

Although the embodiments described herein mainly address vacuum plates used in processes for producing flexible circuit boards, the methods and systems described herein can also be used in other applications, such as in fixing of any thin and/or flexible electronic devices and/or panels, glass display panels, wafers, framed and diced wafers.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A system, comprising:
a plate having a first surface and a second surface opposite the first surface, the plate is configured to receive on the first surface a flexible substrate comprising a first section having a first flexibility and a second section having a second flexibility different from the first flexibility, wherein the plate has through-holes (TH), between the first and second surfaces, with a variable density that varies from a first pattern arranged in a first density opposite the first section to a second pattern arranged in a second density, different from the first density, opposite the second section; and
a vacuum source, which is configured to draw a vacuum in the TH between the first surface and the second surface for fixing the first section to the first pattern and the second section to the second pattern.

2. The system according to claim 1, wherein at least one of the TH has a first cavity extended from the first surface into the plate and having a first shape, and a second cavity that is: (i) extended from the second surface into the plate, (ii) connected to the first cavity and (iii) having a second shape, and wherein at least one of the first shape or the second shape comprises a conical shape.

3. The system according to claim 2, wherein when all the TH have the first cavity, at least twenty percent of the first surface is perforated with the first cavity.

4. The system according to claim 1, wherein at least one of the TH has a diameter, which is measured on the first surface, and is smaller than 1 mm.

5. The system according to claim 1, wherein the plate comprises stainless steel.

6. The system according to claim 1, and comprising one or more pillars, which are formed on the second surface between two or more of the TH that are adjacent, and are configured to improve a uniformity of the vacuum applied through the plate.

7. The system according to claim 6, wherein at least one of the pillars has a conical shape.

8. The system according to claim 1, wherein the flexible substrate has a third section, which is positioned between the first section and the second section and has a third flexibility, which is smaller than the first flexibility and larger than the second flexibility, wherein the plate has a third pattern, which is positioned between the first pattern and the second pattern and is arranged in a third density opposite the third section, and wherein the third density is smaller than the first density and larger than the second density.

9. The system according to claim 8, wherein the variable density varies gradually from the first density to the second density via the third density.

10. The system according to claim 1, wherein the flexible substrate comprises a flexible circuit board, and wherein the vacuum source is configured to draw the vacuum in the TH for performing on the flexible circuit board at least a process selected from a list of processes consisting of: (i) a production process, (ii) a repairing process, and (iii) an inspection process.

11. A method for producing a plate for fixing thereto a flexible substrate comprising a first section having a first flexibility and a second section having a second flexibility different from the first flexibility, the method comprising:
in a plate having a first surface and a second surface opposite the first surface, producing multiple first cavities extended from the first surface into the plate and having a first shape; and
producing multiple second cavities extended from the second surface into the plate and having a second shape, wherein a plurality of the second cavities is connected to a plurality of the first cavities, respectively, and break through the plate for producing multiple through-holes (TH) between the first and second surfaces.

12. The method according to claim 11, wherein the TH are arranged in a variable density that varies from a first pattern arranged in a first density opposite the first section, to a second pattern arranged in a second density, different from the first density, opposite the second section.

13. The method according to claim 12, wherein producing the multiple first cavities comprises applying a first lithography process for defining on the first surface the first pattern and the second pattern of the TH.

14. The method according to claim 13, wherein producing the multiple first cavities comprises applying a first etching process for transferring, into the plate, the first pattern and the second pattern defined in the first lithography process.

15. The method according to claim 14, wherein producing the multiple second cavities comprises applying a second lithography process for defining on the second surface the first pattern and the second pattern of the TH, wherein, in the second lithography process: (i) the first pattern of the second lithography process is aligned with the first pattern of the first lithography process, and (ii) the second pattern of the second lithography process is aligned with the second pattern of the first lithography process.

16. The method according to claim 15, wherein producing the multiple second cavities comprises applying a second etching process for transferring, into the plate, the first pattern and the second pattern defined in the second lithography process, and wherein applying the second etching process comprises breaking through the plate for connecting between the second cavity and the first cavity.

17. The method according to claim 16, wherein at least one of the first and second etching process comprises a wet etching process.

18. The method according to claim 11, wherein at least one of the first and second shapes comprises a conical shape.

19. The method according to claim 11, and comprising producing on the second surface one or more pillars positioned between the second cavities.

20. The method according to claim 19, wherein producing at least one of the pillars by applying to the plate a lithography process and an etching process.
